(19) United States
(12) Patent Application Publication
(10) Pub. No.: US 2021/0261418 A1
(43) Pub. Date: Aug. 26, 2021

(54) METHOD FOR SYNTHESIZING HIGH-PURITY CARBON NANOCOILS BASED ON COMPOSITE CATALYST FORMED BY MULTIPLE SMALL-SIZED CATALYST PARTICLES

(71) Applicant: DALIAN UNIVERSITY OF TECHNOLOGY, Dalian, Liaoning (CN)

(72) Inventors: Lujun PAN, Dalian, Liaoning (CN); Yongpeng ZHAO, Dalian, Liaoning (CN)

(21) Appl. No.: 16/972,902

(22) PCT Filed: Jun. 12, 2020
(86) PCT No.: PCT/CN2020/095757

§ 371 Date: Dec. 7, 2020

(30) Foreign Application Priority Data
Sep. 23, 2019 (CN) 201910899819.9

(51) Int. Cl. C01B 32/18; B01J 35/02; B01J 23/835; B01J 37/00; C23C 16/26; C23C 16/455

(52) U.S. Cl. CPC C01B 32/18; B01J 35/023; B01J 23/835; B82Y 30/00; C23C 16/26; C23C 16/45534; B01J 37/0072

(57) ABSTRACT

The present invention provides a method for synthesizing high-purity carbon nanocoils based on a composite catalyst formed by multiple small-sized catalyst particles, and belongs to the technical field of material preparation. In the present invention, Fe—Sn—O nanoparticles with sizes of less than 100 nm prepared by chemical or physical methods are used as catalysts, and stacked and made into contact in a simple manner, and then carbon nanocoils are efficiently synthesized from the prepared catalysts by a thermal chemical vapor deposition method. The method provided by the present invention has simple process and low cost. In addition, the preset invention discloses a novel carbon nanocoil growth mechanism, which makes the prepared catalyst for carbon nanocoil growth more efficient and easier for industrialized mass production.

### TECHNICAL FIELD

The present invention belongs to the technical field of material preparation, and provides a method for synthesizing a high-purity carbon nanocoil based on a composite catalyst formed by multiple small-sized catalyst particles.

### BACKGROUND

The carbon nanocoils (CNCs) with a spiral morphology have unique physical and chemical properties, and have wide application prospects in composite materials, energy storage, strain sensors, electromagnetic absorption materials, and MEMS systems. Therefore, the efficient preparation of CNCs is essential to expansion of the application fields, and the premise of the efficient preparation is a comprehensive and clear understanding of the synthesis mechanism.

The chemical vapor deposition (CVD) is a production method that is most suitable for large-scale efficient preparation of CNCs, in which the catalyst activity is the most important factor affecting the synthesis efficiency. At present, the synthesis, application, and mechanism researches on the catalyst for the growth of CNCs are focused on the research and application of the anisotropy of the catalytic activity of single-particle catalysts, i.e., the research and application of the influence of the morphology, crystal face, component and size of single-particle catalysts on growth of CNCs [publications: Liu, Wen-Chih, et al. Acs Nano 4.7 (2010): 4149-4157; Wang, Guizhen, et al. ACS nano 8.5 (2014): 5330-5338.]. In addition, the researches show that single-particle catalysts with a size of 100-200 nm are suitable for the growth of spring-like CNCs [publication: Qian, Juanjuan, et al. Journal of nanoscience and nanotechnology 10.11 (2010): 7366-7369.], and catalysts with other particle sizes can only grow into other forms of carbon nanomaterials; and on the other hand, the Fe/Sn catalyst is widely studied due to low preparation cost, wide raw material source, and high catalytic activity. The Fe/Sn catalyst currently reported is usually catalyst particles (100-200 nm) which are prepared from a precursor solution containing Fe/Sn by the sol-gel method and thermal co-deposition and are suitable for the growth of CNCs, but the catalysts prepared by the methods often have wide particle size distribution, small specific surface area, and low content of effective components in the catalysts, which severely restricts the growth efficiency of CNCs. Therefore, how to efficiently prepare a catalyst with a suitable size and component becomes the focus and difficulty of the current research and application.

### SUMMARY

The purpose of the present invention is to provide a method for aggregating small-sized catalyst particles and a method for synergistically high growing carbon nanocoils through the combination of a plurality of small-sized catalysts in view of the problems of complex catalyst synthesis process and low efficiency in the current efficient synthesis process of carbon nanocoils. Different from the previously reported CNC growth with a single nanoparticle as a catalyst, the patent is a method for synergistically growing a CNC from more than two catalyst particles with a size of less than 100 nm as a composite catalyst, which realizes composite catalysis and growth of multi-particle catalysts by means of changing the catalyst stacking density. Compared with large-sized catalysts (larger than 100 nm), small-particle catalysts have a larger specific surface area and more sufficient contact with carbon source gases so as to realize efficient growth of CNCs.

To achieve the above purpose, the present invention adopts the following technical solution: A method for synthesizing a high-purity carbon nanocoil based on a composite catalyst formed by multiple small-sized catalyst particles first prepares Fe—Sn—O nanoparticles with a size of less than 100 nm. The Fe/Sn catalyst is widely studied due to low preparation cost, wide raw material source, and high catalytic activity. The Fe—Sn—O nanoparticles are used as catalysts, and stacked and made into contact in a simple manner, and then a CNC is efficiently synthesized from the prepared catalyst by thermal CVD. The method comprises the followings specific steps:

(1) Preparing Small-Sized Catalysts for Growth of the Carbon Nanocoils

Using a Fe³⁺ salt or a ferric oxide and soluble Sn⁴⁺ salt or a tin oxide as raw materials, and using chemical synthesis methods, physical methods or a combination thereof to prepare composite catalyst powder, wherein the composite catalyst powder is composed of Fe—Sn—O, the molar ratio of Fe to Sn in the catalyst is 5:1-30:1, and the particle size of the catalyst is 10 to 100 nm.

(2) Efficiently catalyzing the growth of carbon nanocoils with the synthesized composite catalyst by adopting CVD method

Dispersing the prepared composite catalyst powder in a solvent such as water or ethanol, where the concentration of the dispersion liquid is 0.01 to 1 mg/ml, and cleaning the substrate. Drop-coating, spin-coating, or spray-coating the catalyst dispersion liquid onto the surface of the substrate, wherein the density range of the catalyst on the surface of the substrate is 1×10⁹/cm⁻² to 5×10¹⁰/cm⁻², and realizing uniform support and mutual accumulation and contact of catalyst particles on the substrate. Putting the dried substrate in a CVD system, and synthesizing the high-purity (larger than 95%) CNCs by CVD method.

Further, in step (1), the soluble Fe³⁺ salt used in the preparation process includes, but is not limited to, ferric chloride, ferric nitrate, ferric sulfate, and the like; the soluble Sn⁴⁺ salt includes tin tetrachloride; the Sn⁴⁺ salt and the Fe³⁺ salt can be combined arbitrarily; and in step (1), the ferric oxide is Fe₂O₃, and the tin oxide is SnO₂.

Further, in step (1), the chemical synthesis methods include a hydrothermal method and a solvothermal method; and the physical methods include a thermal evaporation method, a magnetron sputtering method and a high-speed ball milling method etc.

Further, the substrate in step (2) comprise quartz chips, silicon chips, SiO₂ chips, graphite substrates and stainless steel or alumina substrates, etc.

The principle of efficiently preparing CNCs by the method of the present invention can be summarized as that: the mechanism of synthesizing a carbon nanocoil from catalysts is to use the different catalytic activity of each catalyst nanoparticle to cause the anisotropy of the catalytic activity of the entire composite catalyst. Specifically, small-sized Fe—Sn catalyst particles are stacked and made into contact with each other. In the processes of decomposition, carburization and carbon precipitation of carbon source gases on the surfaces of the catalyst particles at high temperature, a plurality of nearby catalyst particles naturally agglomerate and combine with each other through carbon to form a composite catalyst, wherein fibrous (or tubular) carbon nanowires with different morphologies grown from small catalyst particles adhere to each other. Meanwhile, the differences in the size, morphology, and component of different small catalyst particles result in differences in the rates of decomposition, carburization, and carbon precipitation of the carbon source gas, which makes the composite carbon nanofibers grow in a spiral structure, that is the carbon nanocoil.

The present invention has the following beneficial effect: the small-sized catalyst has a higher specific surface area, which results in higher catalytic activity, higher efficiency and higher product purity.

### DESCRIPTION OF DRAWINGS

FIG. 1 is an EDS element analysis test map of catalyst powder prepared in embodiment 1.

FIG. 2 is a TEM image of catalyst powder prepared in steps a and b in embodiment 1.

FIG. 3 shows a macro SEM image (a) of a CNC prepared after spin-coating of a catalyst dispersion liquid for 30 times in embodiment 1 and an SEM image (b) of a top catalyst of a single CNC.

FIG. 4 is a TEM image of a typical product after spin-coating of a catalyst for 30 times in embodiment 1.

FIG. 5 is a TEM image of catalyst powder prepared in steps a and b in embodiment 2.

FIG. 6 shows a macro SEM image (a) of a CNC prepared after spray-coating of a catalyst dispersion liquid for 20 times in embodiment 2 and an SEM image (b) of a top catalyst of a single CNC.

FIG. 7 is an SEM image of catalyst powder prepared in steps a and b in embodiment 3.

FIG. 8 shows a macro SEM image (a) of a CNC prepared after drop-coating of a catalyst dispersion liquid for 10 times in embodiment 3 and an SEM image (b) of a top catalyst of a single CNC.

### DETAILED DESCRIPTION

The present invention can be understood more easily with reference to the following detailed description of the embodiments, comparative embodiments, and drawings. However, the present invention may be implemented in many different forms and shall not be interpreted to be limited to the embodiments described herein. The embodiments are intended to complete the disclosure of the present invention and inform those skilled in the art of the present invention of the scope of the present invention. The present invention is defined by the scope of the claims. The same reference signs in the whole description refer to same elements.

Hereinafter, the preferred embodiments of the present invention will be described in detail with reference to the drawings, that is, small-particle catalysts synergistically catalyze and efficiently synthesize a carbon nanocoil. In the embodiments described below, the process of synthesizing a carbon nanocoil by CVD is that: acetylene (C₂H₂) is used as the carbon source with the flow rate of 15 sccm, argon (Ar) is the protective gas with the flow rate of 245 sccm, the reaction temperature is 710° C., and the reaction time is 30 min. Natural cooling is conducted after the reaction is over.

### Embodiment 1

(1) Preparing a Small-Sized Catalyst by the Hydrothermal Method (Chemical Method)

The synthesis steps of the embodiment are divided into step a and step b: (a) dissolving 1.2 g of Fe(NO₃)₃.9H₂O in 20 ml of deionized water, using ultrasound to make the mixed solution dissolve completely, adding 15 ml of ammonium hydroxide (with the mass fraction of 15%), dissolving the mixed solution uniformly by ultrasound, transferring the mixed solution to a high-pressure reactor, wherein the reaction temperature is 140° C. and the reaction time is 12 h, naturally cooling to room temperature, and filtering, washing and drying the obtained red precipitates to obtain single red powder.

(b) Dispersing 20 mg of red powder prepared in the above step in 30 ml of water by ultrasound, adding 0.2 g of SnCl₄.5H₂O, adding 1 mol/L NaOH solution dropwise after fully dissolving to adjust PH to 10, transferring the mixed solution uniformly dispersed to a high-pressure reactor, wherein the reaction temperature is 200° C., the reaction time is 1.5 h, and the molar ratio of Fe to Sn in the obtained product is 20:1, naturally cooling to room temperature, and filtering, washing and drying the obtained red precipitates to obtain a red powder.

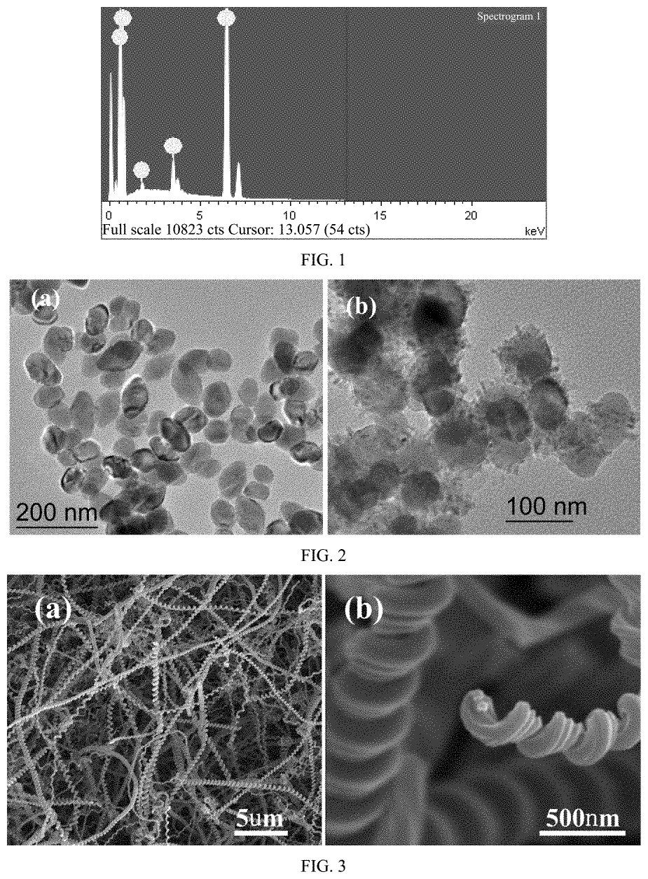

FIG. 1 shows the EDS element analysis test of catalyst powder, and the result shows that the red power is composed of three elements: Fe, Sn, and O; and FIG. 2 is a TEM image of preparation of catalyst powder, from which it can be seen that the distribution range of catalyst particles is 70-100 nm.

(2) Preparing Carbon Nanocoils with the Above Catalyst

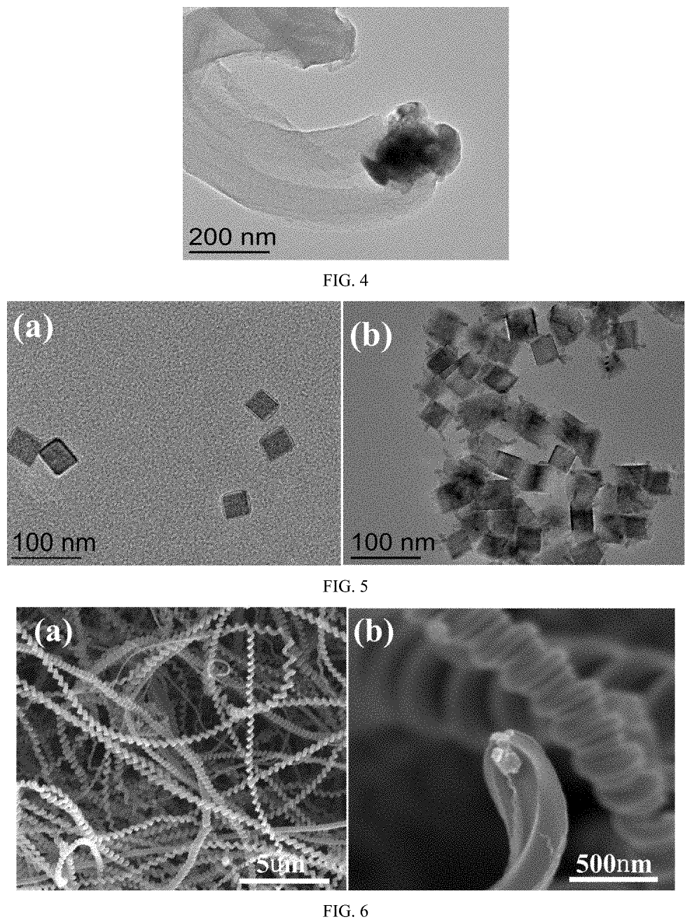

Accurately weighing the catalyst powder prepared in step (1), dispersing in alcohol (concentration: 0.1 mg/ml), cleaning the silicon chip on the reaction substrate with acetone, alcohol and deionized water, and drying for later use. Weighing 0.2 ml of catalyst dispersion liquid, spin-coating onto the surface of the substrate (rotating speed: 2000/min), and repeating the above process for 30 times. FIG. 3 (a) is an SEM image of the product of the CVD reaction of the substrate with the catalyst spin-coated for 30 times, and the purity of the CNC is higher than 95%. FIG. 3 (b) is an SEM image of a top catalyst of the CNC, from which it can be seen that the catalyst on the top of the CNC is in a state of aggregation of a plurality of small particles and is significantly different in the growth mechanism from the single-particle catalyst previously disclosed. FIG. 4 is a TEM image of a typical product, from which it can be been that the catalyst is composed of four catalysts with different sizes, and the differences in the morphology, size, and other characteristics of various catalysts result in a difference in the catalytic activity so as to cause the anisotropy growth of the CNC.

### Embodiment 2

(1) Preparing a Small-Sized Catalyst by the Solvothermal Method (Chemical Method)

The synthesis steps of the embodiment are divided into step a and step b: (a) dissolving 0.526 g of Fe₂(SO₄)₃.7H₂O in 35 ml of N,N-dimethylformamide, using ultrasound to make the mixed solution dissolve completely, finally adding 0.8 g of polyvinylpyrrolidone (PVP), transferring the mixed solution to a reactor after fully dissolving, controlling the reaction temperature to 180° C. and the reaction time to 6 h in the solvent thermal system, naturally cooling to room temperature, and filtering, washing and drying the obtained red precipitates to obtain a red powder.

(b) Dispersing 20 mg of red powder prepared in the above step in 30 ml of water by ultrasound, adding 0.2 g of SnCl₄.5H₂O, adding 1 mol/L NaOH solution dropwise after fully dissolving to adjust PH to 10, transferring the mixed solution uniformly dispersed to a high-pressure reactor, wherein the reaction temperature is 200° C., the reaction time is 2 h, and the molar ratio of Fe to Sn in the obtained product is 10:1, naturally cooling to room temperature, and filtering, washing and drying the obtained red precipitates to obtain single red powder. FIG. 5 is a TEM image of preparation of catalyst powder in steps a and b, from which it can be seen that the distribution range of catalyst particles is 30-50 nm.

(2) Efficiently Preparing Carbon Nanocoils with the Above Catalyst

Accurately weighing the catalyst powder prepared in step (1), dispersing in alcohol (concentration: 0.1 mg/ml), cleaning the silicon chip on the reaction substrate with acetone, alcohol, and deionized water, and drying for later use. Weighing 0.1 ml of catalyst dispersion liquid, spray-coating onto the surface of the substrate, repeating the above process for 20 times, and putting the dried substrate carrying the catalyst in the CVD system for reaction. FIG. 6 (a) is an SEM image of the product of the CVD reaction of the substrate with the catalyst spin-coated for 30 times, and the purity of the CNC is higher than 95%. FIG. 3 (b) is an SEM image of a top catalyst of the CNC, from which it can be seen that the catalyst on the top of the CNC is in a state of aggregation of a plurality of small particles, indicating that the catalyst for the carbon nanocoil is formed by stacking a plurality of small-sized catalysts.

### Embodiment 3

(1) Preparing a Small-Sized Catalyst for a Carbon Nanocoil by the Physical Sputtering Method (Combination of Chemical-Physical Methods)

The synthesis steps of the embodiment are divided into step a and step b: (a) dissolving 0.270 g of FeCl₃.6H₂O in 35 ml of N,N-dimethylformamide, using ultrasound to make the mixed solution dissolve completely, finally adding 0.8 g of polyvinylpyrrolidone (PVP), transferring the mixed solution to a reactor after fully dissolving, controlling the reaction temperature to 180° C. and the reaction time to 6 h in the solvent thermal system, naturally cooling to room temperature, and filtering, washing and drying the obtained red precipitates to obtain single red powder.

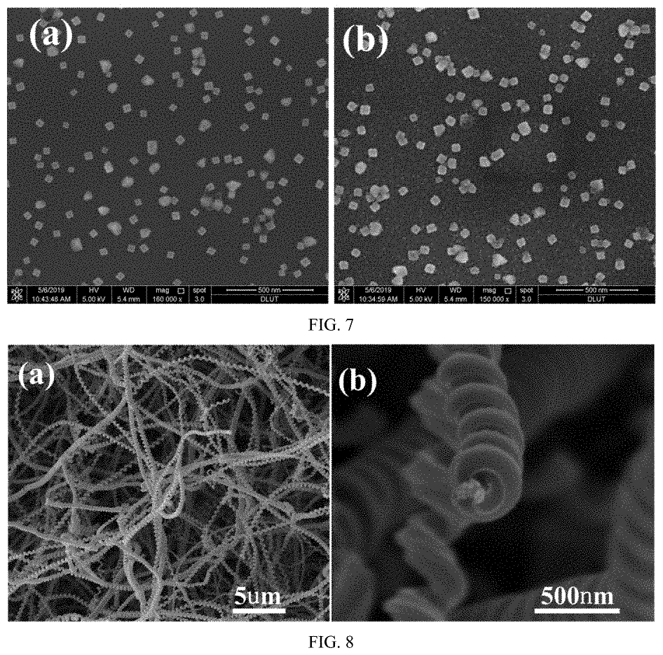

(b) Accurately weighing the catalyst powder prepared in step (a), dispersing in alcohol (concentration: 0.1 mg/ml), cleaning the silicon chip on the reaction substrate with acetone, alcohol and deionized water, and drying for later use. Weighing 0.1 ml of catalyst dispersion liquid, drop-coating onto the surface of the substrate, and putting the dried substrate in a magnetron sputtering instrument to compound SnO₂, wherein the specific parameters are that: the operating current is 60 mA, the operating voltage is 40 mV, the operating power is 20 W, and the deposition time is 3 min. The molar ratio of iron to tin atoms is 30:1. FIG. 8 is an SEM image of catalyst powder prepared in steps a and b, from which it can be seen that the distribution range of the catalyst particles is 30-50 nm.

(2) Preparing the High-Purity Carbon Nanocoils with the Above Catalyst

Repeating step b for 10 times, and putting the dried substrate carrying the catalyst in the CVD system for reaction. FIG. 3 (a) is an SEM image of the product of the CVD reaction of the substrate with the catalyst spin-coated for 30 times, and the purity of the CNC is higher than 95%. FIG. 3 (b) is an SEM image of a top catalyst of the CNC, from which it can be seen that the catalyst on the top of the CNC is in a state of aggregation of a plurality of small particles, indicating that the catalyst for the carbon nanocoil is formed by stacking a plurality of small-sized catalysts.

### Embodiment 4

(1) Preparing a Small-Sized Catalyst for a Carbon Nanocoil by Physical Ball Milling (Physical Method)

Mixing α-Fe₂O₃ (20-50 nm) and SnO₂ (10-20 nm) at a molar ratio of Fe to Sn of 5:1, putting the mixture into a high speed ball mill, wherein the specific parameters are that: the rotating speed is 1000 r/min and the time is 2 H, taking out the catalyst powder after ball milling, and cleaning for later use.

(2) Preparing the Carbon Nanocoils with the Above Catalyst

Accurately weighing a certain amount of catalyst powder prepared in step (1), dispersing in water or organic solution (concentration: 1 mg/ml) to ultrasonically mix for later use, cleaning the silicon chip on the reaction substrate with acetone, alcohol and deionized water, and drying for later use. Weighing 1 ml of catalyst dispersion liquid, and coating onto the surface of the substrate; and putting the dried substrate carrying the catalyst in the CVD system for reaction, and naturally cooling after reaction. The product is the carbon nanocoils.

### Embodiment 5

(1) Preparing a Small-Sized Catalyst for a Carbon Nanocoil by Thermal Evaporation (Chemical-Physical Method)

The synthesis steps of the embodiment are divided into step a and step b:

(a) Dissolving 0.404 g of Fe(NO₃)₃.9H₂O in 35 ml of N,N-dimethylformamide, using ultrasound to make the mixed solution dissolve completely, finally adding 0.8 g of polyvinylpyrrolidone (PVP), transferring the mixed solution to a reactor after fully dissolving, controlling the reaction temperature to 180° C. and the reaction time to 6 h in the solvent thermal system, naturally cooling to room temperature, and filtering, washing and drying the obtained red precipitates to obtain single red powder.

(b) Accurately weighing the catalyst powder prepared in step (a), dispersing in alcohol (concentration: 0.1 mg/ml), cleaning the silicon chip on the reaction substrate with acetone, alcohol and deionized water, and drying for later use. Weighing 0.1 ml of catalyst dispersion liquid, spin-coating onto the surface of the substrate, and putting the dried substrate in a thermal evaporation instrument to compound Sn, wherein the specific parameters are that: the operating current is 1 A, the temperature is 1000° C., and the deposition time is 10 min. The molar ratio of iron to tin atoms is 30:1.

(2) Preparing the High-Purity Carbon Nanocoils with the Above Catalyst

Repeating step b for 10 times, and putting the dried substrate carrying the catalyst in the CVD system for reaction. The product is the high-purity carbon nanocoil.

The above embodiments show that: using the small-sized Fe—S—O catalyst proposed herein can efficiently prepare carbon nanocoils, and meanwhile, the patent proposes At the same time, the above description of the embodiments is to facilitate those skilled in the art to understand and apply the present invention. Those skilled in the art can easily make various modifications to the embodiments, and apply the general principles described herein to other embodiments without contributing creative labor. Therefore, the present invention is not limited to the embodiments descried herein, and improvements and modifications made by those skilled in the art to the present invention according to the disclosure of the present invention shall fall within the protection scope of the present invention.

1. A method for synthesizing high-purity carbon nanocoils based on a composite catalyst formed by multiple small-sized catalyst particles, wherein the method first prepares Fe—Sn—O nanoparticles with a size of less than 100 nm, uses the nanoparticles as a catalyst, and then uses the prepared catalyst to efficiently synthesize carbon nanocoils by method of thermal chemical vapor deposition (CVD), comprising the following steps:
(1) preparing small-sized catalysts for growth of the carbon nanocoils
using a Fe3+ salt or a ferric oxide and a soluble Sn4+ salt or a tin oxide as raw materials, and using chemical synthesis methods, physical methods or a combination thereof to prepare composite catalyst powder, wherein the composite catalyst powder is composed of Fe—Sn—O, the molar ratio of Fe to Sn in the catalyst is 5:1-30:1, and the particle size of the catalyst is 10 to 100 nm;
(2) efficiently catalyzing the growth of carbon nanocoils with the synthesized composite catalyst by adopting CVD method
dispersing the prepared composite catalyst powder in a solvent such as water or ethanol, where the concentration of the dispersion liquid is 0.01 to 1 mg/ml, and cleaning the substrate; drop-coating, spin-coating or spray-coating the catalyst dispersion liquid onto the surface of the substrate, wherein the density range of the catalyst on the surface of the substrate is 1×109/cm−2 to 5×1010/cm−2, and realizing uniform support and mutual accumulation and contact of catalyst particles on the substrate; and putting the dried substrate in a CVD system, and synthesizing the high-purity carbon nanocoils by CVD, wherein the purity of the carbon nanocoils is larger than 95%.

2. The method for synthesizing high-purity carbon nanocoils based on a composite catalyst formed by multiple small-sized catalyst particles according to claim 1, wherein the step (1), the soluble Fe3+ salt used in the preparation process includes, but is not limited to, ferric chloride, ferric nitrate, ferric sulfate and the like; the soluble Sn4+ salt includes tin tetrachloride; the Sn4+ salt and the Fe3+ salt can be combined arbitrarily; and in step (1), the ferric oxide is Fe₂O₃, and the tin oxide is SnO₂.

3. The method for synthesizing high-purity carbon nanocoils based on a composite catalyst formed by multiple small-sized catalyst particles according to claim 1, wherein the step (1), the chemical synthesis methods include a hydrothermal method and a solvothermal method; and the physical methods include a thermal evaporation method, a magnetron sputtering method and a high speed ball milling method.

4. The method for synthesizing high-purity carbon nanocoils based on a composite catalyst formed by multiple small-sized catalyst particles according to claim 1, wherein the substrates used in step (2) comprise quartz chips, silicon chips, SiO2 chips, graphite substrates and stainless steel or alumina substrates.

5. The method for synthesizing high-purity carbon nanocoils based on a composite catalyst formed by multiple small-sized catalyst particles according to claim 3, wherein the substrates used in step (2) comprise quartz chips, silicon chips, SiO2 chips, graphite substrates and stainless steel or alumina substrates.
